(19) United States
(12) Patent Application Publication
(10) Pub. No.: US 2010/0026322 A1
(43) Pub. Date: Feb. 4, 2010

(54) Method for ascertaining burden resistance for a measurement transmitter

(75) Inventors: Martin Gehrke, Weinstadt (DE); Matthias Knopp, Weissach-Flacht (DE)

Correspondence Address: BACON & THOMAS, PLLC, 625 SLATERS LANE, FOURTH FLOOR, ALEXANDRIA, VA, 22314-1176, US

(73) Assignee: Endress+Hauser Conducta Gesellschaft fur Mess- und Regeltechnik mbh + Co. KG

(21) Appl. No.: 12/308,761

(22) PCT Filed: Jun. 14, 2007
(86) PCT No.: PCT/EP2007/055909

§ 371 Date: Oct. 2, 2009

(30) Foreign Application Priority Data
Jun. 30, 2006 (DE) 10 2006 030 774.7

(51) Int. Cl. G01R 27/08

(52) U.S. Cl. 324/691

(57) ABSTRACT

In a method for ascertaining burden resistance for a measurement transmitter, which is supplied with voltage via a first line-pair and which transmits a variable electrical-current signal via an electrical-current loop to a control system via a second line-pair, a test-voltage signal is capacitively coupled into the electrical-current loop and an associated electrical-current signal evaluated. An instantaneous value of the burden resistance is ascertained from a characterizing feature of the electrical-current signal, especially an RC time constant. Thus, already at start-up of a measurement transmitter, a burden resistance, which is too high, can be detected.

The invention relates to a method for ascertaining burden resistance for a measurement transmitter, as such method is defined in the preamble of claim 1.

In process automation technology, measurement transmitters are often applied for transmitting to process control systems, measured values as analog, 4-20 mA signals. In the process control system, the voltage drop, which the 4-20 mA signal causes on a burden resistance, is evaluated. Depending on the supply voltage available in the measurement transmitter, the burden resistance cannot exceed a certain maximum value, in order that the full measuring range can be transmitted by the measurement transmitter to the control system.

A design burden-resistance, which is too large, should be detected already at start-up of a measurement transmitter. Otherwise, certain measured values can possibly be transmitted corrupted to the control systems.

With todays known methods for monitoring a burden resistance, such being frequently referred to simply as burden monitoring, besides too large, design burden-resistances, also line breaks in the connecting lines for the 4-20 mA signal can be recognized. For this, various methods are known, of which two will be explained as follows.

In a first method, the current controller, with which the 4-20 mA signal is tuned, is monitored. If the burden resistance is too high, then the control error signal can no longer be erased by the controller. If the control error signal remains over a longer period of time at a certain level, then this is a reliable indication that the burden resistance has a value, which is too large. If this situation occurs only in the case of extremes of measured values, then, at start-up of the measurement transmitter, it is not assured, that the too large burden resistance will be immediately recognized. It cannot be excluded, that such an extreme measured value then occurs with a considerable time delay. Therewith, the error is not detected at start-up, but, instead, then with a considerable time delay.

A further method of burden monitoring is to monitor the feeding voltage, which must decline upon connection of a burden resistance, due to the internal resistance of the applied voltage source. If the voltage is too high with connected burden resistance, then this indication of an incorrect burden resistance, or even a line break.

Another method of burden monitoring is to digitize the supply voltage and the instantaneously flowing current and to calculate therefrom, using Ohm's law, the instantaneous burden resistance.

The two, first-discussed methods are simple to implement; they possess, however, the disadvantage, that an incorrect, i.e. a too large, burden resistance is then detected usually only with significant time delay.

Preventative, or proactive, measures are not possible in the case of the two, first-discussed methods.

The last method yields comprehensive information concerning the state of the electrical-current loop, especially via the exact value of the burden resistance. It enables, thus, a risk evaluation of the electrical-current loop and, thus, of the entire measuring system. It is, however, associated with considerable electronic complexity in the measurement transmitter, especially when a galvanic separation is required in the measurement transmitter between the actual evaluating-circuit and the electrical-current loop.

With the last method, it is, however, possible to assure, that a too high burden resistance is detected already at start-up of the measurement transmitter.

An object of the invention is, therefore, to provide a method for ascertaining burden resistance for a measurement transmitter, which method does not have the above mentioned disadvantages, while being, especially, easy and cost-favorable to implement.

This object is achieved by the method features defined in claim 1. Advantageous further developments of the invention are presented in the dependent claims.

An essential idea of the invention is to couple a test-voltage signal capacitively into the electrical-current loop, to evaluate the associated electrical-current signal and to ascertain the value of the burden resistance from a characterizing feature of the electrical-current signal.

The invention will now be explained in greater detail on the basis of an example of an embodiment shown in the drawing, the sole figure of which shows as follows:

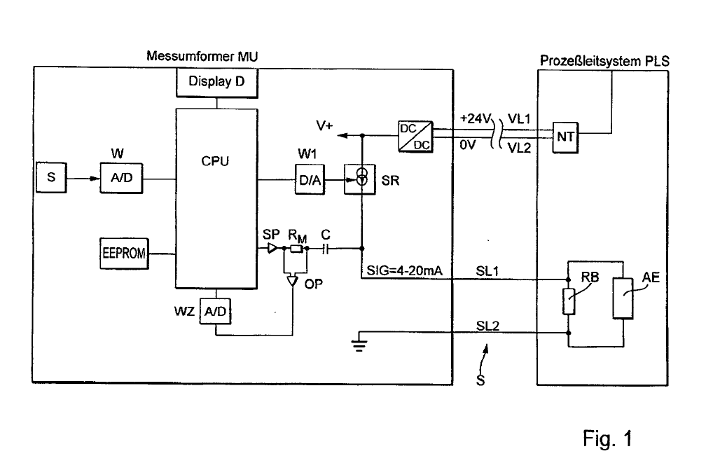

FIG. 1 in schematic presentation, a four-wire measurement transmitter connected with a process control system.

FIG. 1 shows, schematically, a measurement transmitter MT and a process control system PCS, which are connected with one another in four-wire technology via two line-pairs. The measurement transmitter MT includes a measuring transducer S for registering a measured value (e.g. temperature, pressure, pH-value, etc.). The output signal of the measuring transducer S is digitized in an analog-digital converter CV and then sent to a microprocessor CPU, where the measurement signal is conditioned. The conditioned measurement signal is then transmitted, via a 4-20 mA, electrical-current loop L, to the process control system PCS. For this, the microprocessor CPU correspondingly controls a current controller CC by way of a digital-analog converter CV1. The conditioned, measurement signal is used to set the 4-20 mA signal SIG. The electrical-current loop, signal line SL is composed essentially of two signal lines SL1 and SL2 (the second line-pair), which are connected with a burden resistance R_{B} in the process control system. Via the burden resistance R_{B}, the 4-20 mA signal SIG is sensed in the process control system PCS and appropriately evaluated in an evaluating unit EU, in order e.g. to initiate appropriate control procedures.

Most often, process control systems are connected with additional sensors, and, depending on what the particular situation requires, also with actuators (e.g. valves).

Voltage supply of the measurement transmitter is accomplished via two separate supply lines VL1 and VL2 (the first line-pair), which are connected with a power supply PS in the process control system PCS. These two lines lead to a DC-DC converter, which delivers a supply voltage V+ for supplying the different electrical components in measurement transmitter MT.

Serving for presenting especially the instantaneous measured value on-site at the measurement transmitter MT is a display D, which likewise is connected with the microprocessor CPU.

According to the invention, a test-voltage signal is coupled into the signal line SL. To accomplish this, a signal output of the microprocessor CPU feeds through an operational amplifier SB serving as signal buffer, a measuring resistance RM and a capacitor C, to the signal line SL1. The voltage drop across the measuring resistance R_{M} is registered via an operational amplifier OP and fed back to the microprocessor CPU in digital form via an analog-digital converter CV2.

In the following, the method of the invention will now be explained in greater detail.

In a method step a), a test-voltage signal is produced in the measurement transmitter MT and coupled via the capacitor C into the electrical-current loop SL. At the measuring resistance R_{M}, the electrical-current signal associated with the test-voltage signal is registered (method step b) and fed back to the microprocessor CPU. In the microprocessor CPU, in method step c), the electrical-current signal is evaluated. In accordance with the known exponential behavior of capacitor charge/discharge, the resistance value of the burden resistance RB can be ascertained in the microprocessor CPU from a characteristic feature of the current signal, e.g. via the time constant RC (method step d).

Advantageously, the test-voltage signal is a rectangular signal.

In a simplified, curve evaluation, the RC time constant can be ascertained via two values of the electrical-current signal at different points in time t1 and t2.

The producing and evaluating of the test signal is accomplished with assistance of the microprocessor CPU provided in the measurement transmitter MT.

If a too high burden resistance is ascertained, then an error signal can be generated in the measurement transmitter MT and appropriately displayed to the user (burden resistance too high).

The method of the invention enables detection of a too high burden resistance already at start-up of the measurement transmitter. If the burden resistance is actually too high, then the measurement transmitter can generate a corresponding alarm signal and the error can be removed already at start-up. Therewith, a safe, measured-value transmission to the process control system PCS over the entire measuring range 4-20 mA is assured.

Through the capacitive coupling of the test-voltage, the invention is suited especially for measurement transmitters having galvanic separation.

1-6. (canceled)

7. A method for ascertaining burden resistance for a measurement transmitter, which is supplied with voltage via a first line-pair and which transmits a variable measurement signal to a control system via a second line-pair of an electrical-current loop, wherein the measurement signal is controlled by the measurement transmitter and sensed in the process control system at the burden resistance, comprising the steps of:
producing a test-voltage signal in the measurement transmitter and coupling the test-voltage signal via a capacitor, into the electrical-current loop;
registering an electrical-current signal associated with the test-voltage signal;
evaluating the electrical-current signal in the measurement transmitter; and
ascertaining a resistance value of the burden resistance from a characterizing feature of the electrical-current signal.

8. The method as claimed in claim 7, wherein:
the test-voltage signal is a rectangular signal.

9. The method as claimed in claim 8, wherein:
an RC time constant serves as the characterizing feature of the electrical-current signal.

10. The method as claimed in claim 9, wherein:
the RC time constant is ascertained via measuring of two values of the electrical-current signal at different points in time.

11. The method as claimed in claim 7, wherein:
said steps of producing of the test-voltage signal and said step of evaluating of the electrical-current signal occurs in a microprocessor provided in the measurement transmitter.

12. The method as claimed in claim 7, wherein:
further comprising the step of:
generating an error signal when the resistance value of the burden resistance exceeds a limit value.
